(19) United States
(12) Patent Application Publication
(10) Pub. No.: US 2026/0333576 A1
(43) Pub. Date: Oct. 22, 2026

(54) MODULAR CIRCUITS WITH FLEXIBLE PANEL AREAS AND STRETCHABLE TAILS

(71) Applicant: Tacta Systems Inc., Palo Alto, CA (US)

(72) Inventors: David Bibl, Scotts Valley, CA (US); Andreas Bibl, Los Altos, CA (US); Nahid Harjee, Sunnyvale, CA (US)

(21) Appl. No.: 19/181,722

(22) Filed: Apr. 17, 2025

(51) Int. Cl. H05K 1/02; G01L 1/22; H05K 3/36

(52) U.S. Cl. CPC H05K 1/0283; G01L 1/2206; G01L 1/2287; H05K 1/0271; H05K 1/028; H05K 3/361; H05K 2201/051; H05K 2201/053; H05K 2201/057; H05K 2201/058; H05K 2201/10151

(57) ABSTRACT

A modular circuit may include a flexible panel area, circuitry coupled to the flexible panel area, and a stretchable tail coupled to the flexible panel area. The flexible panel area and the stretchable tail may comprise discrete flexible circuit boards. The circuitry may include, for example, sensors of a sensor array, display pixels, radio frequency circuits, conductive traces, etc. The stretchable tail may include a plurality of conductive traces extending along a length of the stretchable tail. The plurality of conductive traces may be coupled to the circuitry of the flexible panel area. The modular circuit may be coupled to an article, such as a sensing glove, video display, or mobile device. Other aspects are also described and claimed.

### BACKGROUND

### Field

This disclosure relates generally to electronic circuitry and, more specifically, to modular circuits with flexible panel areas and stretchable tails, including manufacture and applications of same. Other aspects are also described.

### Background Information

Flexible circuit boards, also referred to as flex circuits or flexible substrates, include printed circuit boards designed to implement electronic circuitry and components for various applications while providing an amount of flexing and bending. Some applications of flexible circuit boards include circuitry for computers, printers, cameras, smart phones, laptops, tablets, and other devices. The flexing and bending enables the flexible circuit boards and their circuitry to be adaptable to many different form factors and shapes.

Flexible circuit boards typically utilize flexible plastic substrates, such as polyimide, to enable the flexing and bending. They may be manufactured with circuitry using similar techniques as traditional rigid circuit boards. Thus, flexible circuit boards may conveniently enable circuitry to be implemented in many different applications that may not be suitable for rigid circuit boards.

### SUMMARY

Embodiments of this disclosure include bonding a first flexible circuit board providing a flexible panel area to a second flexible circuit board providing a stretchable tail. The flexible panel area may include circuitry coupled thereto, such as sensors of a sensor array, display pixels, radio frequency (RF) circuits, conductive traces, etc. The stretchable tail may include conductive traces that are electrically connected to the circuitry of the flexible panel area to enable communications with the circuitry. The stretchable tail may be bendable, stretchable, and deformable in multiple directions based on coiling (e.g., forming in a helix). This may enable forming an array of circuitries that may be coupled or adhered to an article that involves tight curves, complex shapes, and/or a high SNR.

Some embodiments may include a modular circuit, including a flexible panel area, circuitry coupled to the flexible panel area, and a stretchable tail coupled to the flexible panel area. The flexible panel area and the stretchable tail may comprise discrete flexible circuit boards. The stretchable tail includes a plurality of conductive traces extending along a length of the stretchable tail. The plurality of conductive traces may be coupled to the circuitry. The stretchable tail may be coiled in a helix. The stretchable tail may be encapsulated in an elastomer that increases recovery from stretching. A coil of the stretchable tail may be filled with an elastomer that increases recovery from stretching. The stretchable tail may include a shape memory material, e.g., a polymer or alloy, which coils the stretchable tail. The plurality of conductive traces may include first exposed conductors at a first end of the stretchable tail bonded to the circuitry and may include second exposed conductors at a second end of the stretchable tail. The plurality of conductive traces may implement a digital bus for communicating with the circuitry. The circuitry may include a plurality of sensors for sensing an environment. The circuitry may include analog front end (AFE) circuitry to amplify and filter analog signals and an analog to digital converter (ADC) circuitry to produce digital signals.

Some embodiments may include a method for manufacturing a modular circuit, including coupling circuitry to a flexible panel area, coupling a stretchable tail to the flexible panel area, wherein the stretchable tail includes a plurality of conductive traces extending along a length of the stretchable tail, the plurality of conductive traces coupled to the circuitry, and coiling at least a portion of the stretchable tail (before or after coupling the stretchable tail to the flexible panel area). In some embodiments, coupling the stretchable tail may include bonding exposed conductors of the plurality of conductive traces to exposed conductors of the circuitry. In some embodiments, coiling may include wrapping the stretchable tail around a mandrel. In some embodiments the method may include curing, annealing, or setting the stretchable tail to normalize stresses of the stretchable tail after coiling. In some embodiments, coiling includes exposing a shape memory material of the stretchable tail to a transition temperature. In some embodiments, coiling may include releasing the stretchable tail from a carrier to enable a shape memory material to coil the stretchable tail. In some embodiments, the method may include encapsulating the stretchable tail in an elastomer after coiling to increase recovery from stretching of the stretchable tail.

Some embodiments may include a modular system, including a plurality of flexible panel areas coupled to an article, each flexible panel area having circuitry coupled thereto, and a stretchable tail coupled between flexible panel areas of the plurality of flexible panel areas, wherein the stretchable tail includes a plurality of conductive traces extending along a length of the stretchable tail, the plurality of conductive traces coupled to the circuitry of the flexible panel areas. Other aspects are also described and claimed. In some embodiments, the article may be a sensing glove with digits having digit sections defined by knuckles, wherein the plurality of flexible panel areas is arranged to cover digit sections of a digit. In some embodiments, the article may be a sensing glove with digits having digit sections defined by knuckles, wherein each stretchable tail is coupled to a digit along a knuckle.

The above summary does not include an exhaustive list of all aspects of the present disclosure. It is contemplated that the disclosure includes all systems and methods that can be practiced from all suitable combinations of the various aspects summarized above, as well as those disclosed in the Detailed Description below and particularly pointed out in the Claims section. Such combinations may have particular advantages not specifically recited in the above summary.

### BRIEF DESCRIPTION OF THE DRAWINGS

Several aspects of the disclosure herein are illustrated by way of example and not by way of limitation in the figures of the accompanying drawings in which like references indicate similar elements. It should be noted that references to “an” or “one” aspect in this disclosure are not necessarily to the same aspect, and they mean at least one. Also, in the interest of conciseness and reducing the total number of figures, a given figure may be used to illustrate the features of more than one aspect of the disclosure, and not all elements in the figure may be required for a given aspect.

FIG. 1 is an example of a modular circuit with a stretchable tail that is uncoiled.

FIG. 2 is an example of a modular circuit with a stretchable tail that is coiled.

FIG. 3A is a close up view of an example of a modular circuit.

FIG. 3B is an example of a flexible panel area without a stretchable tail.

FIG. 3C is an example of a stretchable tail in an uncoiled stated.

FIG. 3D is an example of a stretchable tail in a coiled state.

FIG. 3E is a first example of a stretchable tail configured as a strain sensor.

FIG. 3F is a second example of a stretchable tail configured as a strain sensor.

FIG. 4 is a first example of a cross section of a stretchable tail that is coiled.

FIG. 5 is a second example of a cross section of a stretchable tail that is coiled.

FIG. 6 is an example of a plurality of modular circuits in an array.

FIGS. 7-10 illustrate manufacturing a modular circuit with layering.

FIGS. 11-15 illustrate manufacturing a modular circuit with a tool.

FIG. 16 is a first example an application that includes modular circuits.

FIG. 17 is a second example an application that includes modular circuits.

FIG. 18 is an example of a process for manufacturing modular circuits.

### DETAILED DESCRIPTION

A sensor array may refer to a group of sensors used for collecting information about an environment. Sensors of a sensor array may be arranged in a certain geometric configuration or pattern. Sensor arrays may enable collecting information over a greater area than a single sensor, and in two or three dimensions of the environment.

In operation, a sensor of a sensor array can generate an output signal indicating detection of a physical phenomenon. For example, a piezoelectric sensor can utilize the piezoelectric effect and/or the pyroelectric effect to detect changes in pressure, acceleration, temperature, strain, or force by converting such detections to electrical charge. In another example, a capacitive sensor can utilize capacitive sensing to detect an object in proximity that may be conductive or may have a dielectric constant that is different from air.

Large area sensor arrays may be limited by the large, rigid sensors of which they are comprised. These sensors may limit the minimum bending radius of curvature and elongation of the substrate. Large area sensor arrays may also be limited by a sensor fill factor (or sensor density) which limits the overall area available for routing electrical interconnects to and from each of the sensors. They may also be limited by the long wires and connections over which small analog signals, produced by the sensors, may be subject to noise, interference, attenuation, and other signal integrity issues. As a result, applications of sensor arrays are typically limited to environments that do not involve tight curves, complex shapes, and/or a high signal-to-noise ratio (SNR).

Embodiments of this disclosure address problems such as these by bonding a first flexible circuit board providing a flexible panel area to a second flexible circuit board providing a stretchable tail. The flexible panel area may include circuitry coupled thereto, such as sensors of a sensor array, display pixels, RF circuits, conductive traces, etc. The stretchable tail may include conductive traces that are electrically connected to the circuitry of the flexible panel area to enable communications with the circuitry. The stretchable tail may be bendable, stretchable, and deformable in multiple directions based on coiling (e.g., forming a helix in a coiled state). The stretchable tail may be analogous to bullion wire or French wire. This may enable forming an array of circuitries that may be coupled or adhered to an article that involves tight curves, complex shapes, moveable areas, and/or a high SNR, such as connectivity over a knuckle or joint of a sensing glove.

In some embodiments, a plurality of modular circuits may be coupled together via the stretchable tails to form an array of circuitries at discrete locations. The array of circuitries may be further bendable, stretchable, and deformable in 3D by stretching and bending of the stretchable tails. The array of circuitries may be coupled to an article including complex shapes and contours to deform with the shapes and contours of the article while providing functionality of the circuitries. For example, the array of circuitries may be a sensing array coupled to a wearable article, such as a sensing glove, shoe, sock, or sleeve, or coupled to an article in the environment, such as a chair or dashboard of a vehicle. In another example, the array of circuitries may form a foldable video display with pixels. In other examples, some of the array of circuitries may be different from others, including controllers, RF communications, etc.

In some embodiments, the modular circuit may be formed by one or more processes that include layering the flexible panel area, layering the stretchable tail, coupling the flexible panel area to the stretchable tail, coiling the stretchable tail (before or after coupling the flexible panel area to the stretchable tail), and/or coupling or adhering the flexible panel area with the stretchable tail to an article. In some cases, a tool, such as a cylindrical mandrel and/or other rolling tool, may be used to coil the stretchable tail. In some cases, a shape memory material, e.g., a polymer or alloy, may be used to coil the stretchable tail. In some cases, a material layer, e.g., a polymer or alloy, may be used to maintain a helical shape. In some cases, an elastomer may be applied to the stretchable tail (inside and/or outside) to increase recovery of the stretchable tail from stretching.

In various embodiments, description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

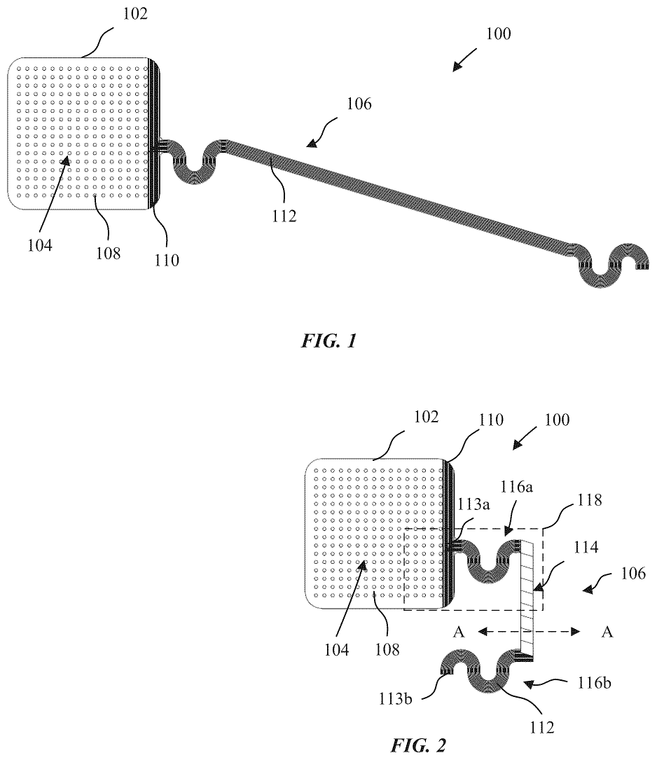

FIG. 1 is an example of a modular circuit 100 with a stretchable tail 106 in an uncoiled state. The modular circuit 100 may include a flexible panel area 102, circuitry 104 coupled to the flexible panel area 102, and the stretchable tail 106 coupled to the flexible panel area 102. The flexible panel area 102 may comprise a first flexible circuit board and the stretchable tail 106 may comprise a second flexible circuit board (e.g., discrete flexible circuit boards, manufactured separately from one another). In some embodiments, a single flexible circuit board including both the flexible panel area 102 and the stretchable tail 106 may be manufactured together as a single unitary body. The flexible panel area 102 and the stretchable tail 106 may be electrically and mechanically coupled together, bonded to one another. For example, in some embodiments, the flexible panel area 102 and the stretchable tail 106 may be bonded to one another via anisotropic conductive film (ACF), an adhesive interconnect bonding that provides electrical conductivity and mechanical coupling. The flexible panel area 102 coupled to the stretchable tail 106 may together form the modular circuit 100.

The circuitry 104 may include, for example, sensors of a sensor array, display pixels, RF circuits, conductive traces, etc. The flexible panel area 102 may have a reduced size to accommodate the circuitry 104, which may include an array of micro scale components at discrete locations, e.g., in a grid. For example, as illustrated, the circuitry 104 includes a plurality of sensors 108 in a sensor array for sensing conditions in an environment (e.g., a sensor array of 16×16 sensors 108 shown). The sensors 108 may be micro scale components that include force sensors, temperature sensors, proximity sensors, and/or light sensors. The sensors 108 may be implemented by piezoelectric devices (e.g., force, temperature, and/or proximity sensing), photo sensitive devices (e.g., light sensing), and/or other electronics. The sensor array may be a single modal or multimodal sensing array of a given sensing type. The sensor array may be coupled to, for example, a fingertip of a sensing glove. Each sensor 108 may have a lateral dimension that is less than 1000 μm, arranged in the flexible panel area 102 with a pitch of 2 mm or less between one another. In some embodiments, the circuitry 104 may include AFE circuitry to amplify and filter analog signals derived from sensing by the sensors 108. The circuitry 104 may also include ADC circuitry to produce digital signals (digital outputs) from the analog signals produced by the sensors 108. The circuitry 104 may include conductive traces 110, extending from an interior to a side of the flexible panel area 102, connected to other elements of the circuitry, e.g., the sensors 108. The conductive traces 110 may include exposed conductors or pads to enable bonding with conductors of the stretchable tail 106.

The stretchable tail 106 may include a plurality of conductive traces 112 extending along a length of the stretchable tail 106. The stretchable tail 106 may have an equivalently reduced size (matching traces of the flexible panel area 102) to route the conductive traces 112 to the micro scale components. For example, the stretchable tail 106 may be less than 50 mm in length, and may be coiled with a diameter of less than 1 mm. The reduced size may enable coupling or adhering the flexible panel area 102 and the stretchable tail 106, forming the modular circuit 100, to a small area of an article that may be deformable in 3D, e.g., a fingertip of a sensing glove. Specifically, the conductive traces 112 may be electrically coupled to the circuitry 104 of the flexible panel area 102 to enable communications with the circuitry 104.

In some embodiments, a digital bus (e.g., a multi conductor circuit) may be implemented by the stretchable tail 106 for communicating with the circuitry 104. A digital controller can access the circuitry 104 via the conductive traces 112 to perform functions in an application, such as triggering sensors 108 and reading their digital outputs. The conductive traces 112 may be limited, for example, to a group of 6 conductors or less for providing power and control via the digital bus. This small group of conductors may enable the stretchable tail to be narrow to further accommodate stretching and bending. In some embodiments, the stretchable tail may be less than 500 μm wide, and in some cases less than 250 μm wide, for tight coiling, and may have a length of 100 mm or less, and in some cases, 50 mm or less. The length may be determined to implement a density of circuitries in an array of circuitries.

FIG. 2 is an example of the modular circuit 100 with the stretchable tail 106 in a coiled state. In the coiled state, at least a portion of the stretchable tail 106 may be coiled in a helix 114 (analogous to a spring) to be bendable, stretchable, and deformable in multiple directions. A first end 116a (proximal) of the stretchable tail 106 may be left uncoiled and bonded to the flexible panel area 102. Further, a second end 116b (distal) of the stretchable tail 106, opposite the first end 116a, may be left uncoiled to be bonded to another flexible panel area, to produce a chain of modular circuits (flexible panel areas bonded to one another via stretchable tails). At the end of the chain, a last stretchable tail may be electrically terminated or deleted. A mid-section of the stretchable tail 106, between the first end 116a and the second end 116b, and which may be longer than either the first end 116a or the second end 116b, may be coiled in the helix 114 to enable stretching and bending between flexible panel areas.

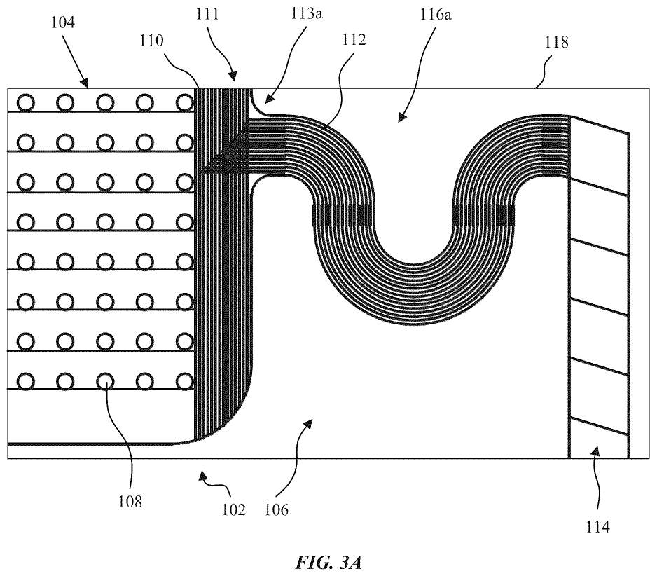

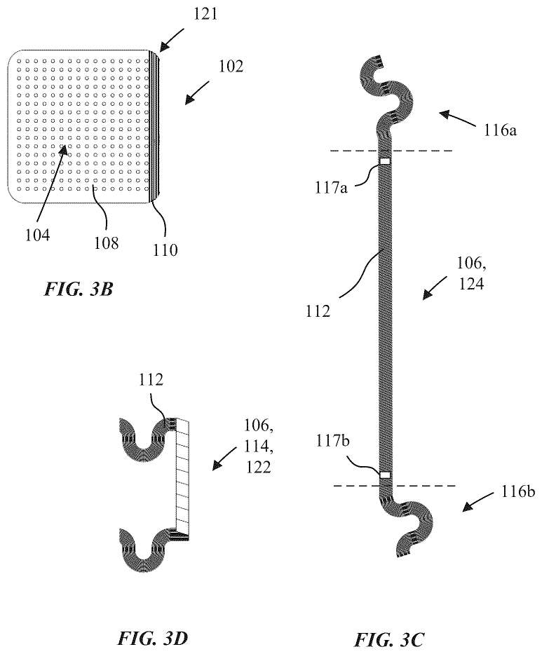

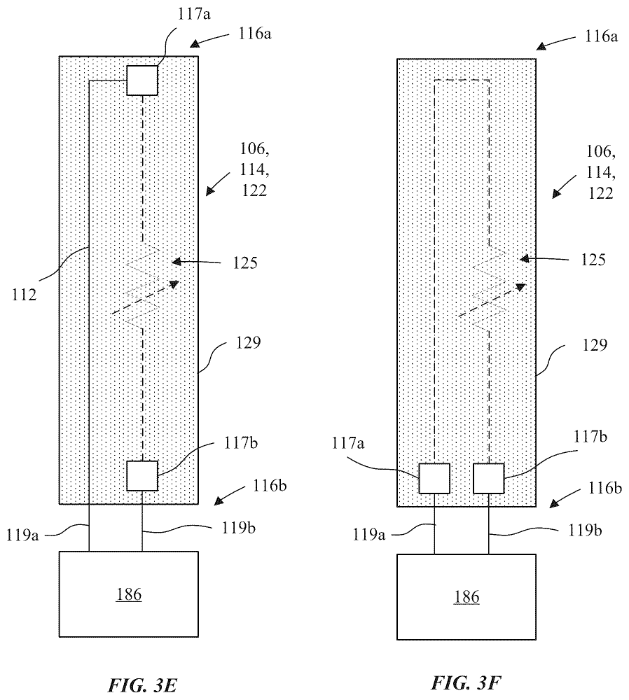

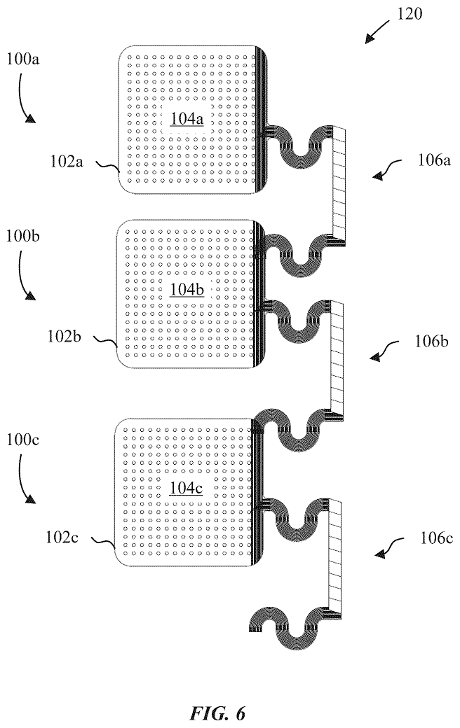

FIG. 3A is a close up view 118 of the modular circuit 100. As may be seen in FIG. 3A, the circuitry 104 of the flexible panel area 102 includes sensors 108 coupled to the conductive traces 110. For example, the sensors 108 may be connected in a daisy chain so that each sensor 108 may receive digital input from a conductive trace, such as a trigger, and provide a digital output via conductive trace to indicate a sensed condition, such as an amount of force, temperature, proximity, and/or light sensing timed with the trigger. The conductive traces 110 may include exposed conductors 111 or pads to enable bonding with conductors of the stretchable tail 106 with electrical connectivity. The first end 116a of the conductive traces 112 of the stretchable tail 106 may also include exposed conductors 113a or pads (first exposed conductors) to enable bonding with conductors of the flexible panel area 102 with electrical connectivity. For example, the flexible panel area 102 and the stretchable tail 106 may be mechanically bonded to one another, and the exposed conductors 111 and the exposed conductors 113a may be electrically bonded to one another, via ACF. The second end 116b of the conductive traces 112 of the stretchable tail 106 may also include exposed conductors 113b or pads (second exposed conductors) to enable bonding to another flexible panel area with electrical connectivity, see, e.g., FIG. 6, or termination if not deleted at the end of chain. The stretchable tail 106 may be bendable, stretchable, and deformable in multiple directions, relative to the flexible panel area 102, based on coiling in the helix 114. This may enable forming an array of circuitries that may be adhered to an article that involves tight curves, complex shapes, and/or a high SNR, such as a sensing glove, video display, or mobile device.

In some embodiments, the flexible panel area 102 and one or more stretchable tails 106 may be manufactured together as a single unitary component forming a modular circuit 100. In some embodiments, the flexible panel area 102 and the stretchable tail 106 may be manufactured as separate, modular components that are subsequently attached or coupled to one another to form a modular circuit 100. The separate, modular components may provide flexibility for various applications which may benefit from customized placement of stretchable tails 106. For example, FIG. 3B illustrates a flexible panel area 102 manufactured as a single modular component without a stretchable tail 106. One or more stretchable tails 106, manufactured separately from the flexible panel area 102, and either uncoiled or coiled, may then be coupled to the flexible panel area 102 at any open area along an edge 121 desired. (e.g., having the conductive traces 110). For example, the one or more stretchable tails 106 may be coupled via ACF bonding with the conductive traces 110 along the edge 121. This may provide great flexibility in applications having tightly controlled spaces. FIG. 3C illustrates a stretchable tail 106 manufactured in an uncoiled state 122. FIG. 3D illustrates a stretchable tail 106 manufactured in a coiled state 124. The stretchable tail 106 may be manufactured, including with the conductive traces 112, independently of the stretchable tail 106. In some cases, the stretchable tail 106 in the uncoiled state 122 may be coupled to the flexible panel area 102 to form the modular circuit 100. Then, after coupling, the stretchable tail 106 may be transformed into the coiled state 124. In other cases, the stretchable tail 106 may be coiled into the coiled state 124, then after coiling, coupled to the flexible panel area 102.

In some embodiments, the stretchable tail 106 may be configured to perform as a strain sensor or strain gauge. The stretchable tail 106 may be filled with a conductive polymer 129 for measuring strain, e.g., a variable resistance, across a cylinder of conductive polymer 129 formed inside the helix 114. For example, the conductive polymer 129 may comprise a polymer or elastomer impregnated with conductive particles to function as a force sensitive resistor. In some cases, the conductive polymer 129 may make electrical contact through the flexible circuit board of the stretchable tail 106 by an electrically conductive via (e.g., via 148 shown in FIGS. 8 and 12). This strain measurement, in turn, may enable a controller to determine an amount of elongation or stretch that the stretchable tail 106 is experiencing which, in turn, may enable determining a position of the flexible panel area 102 and the surface to which it is adhered, e.g., a digit, digit section, or fingertip of a sensing glove.

For example, FIG. 3D illustrates first and second electrical contact areas 117a and 117b, respectively. The electrical contact areas may include exposed pads on an interior surface of the helix 114 when formed to electrically contact the conductive polymer 129 filling inside the helix 114. In the embodiment shown, the contact areas may be arranged at opposite ends of a section of the stretchable tail 106 formed into the helix 114. For example, with additional reference to FIG. 3E, the first electrical contact area 117a may be formed near the first end 116a and the second electrical contact area 117b may be formed near the second end 116b. Further, first and second electrical lines 119a and 119b may connect to the first and second electrical contact areas 117a and 117b, respectively. When the helix 114 is formed as shown in FIG. 3D, and filled with the conductive polymer 129, the first and second electrical contact areas 117a and 117b, respectively, contact the conductive polymer 129 at the opposing ends. A conductive trace 112 may be connected to the first electrical contact area 117a by an electrically conductive via to provide a return path. This may enable a measurement of a variable resistance 125 of the conductive polymer 129 due to strain. The first and second electrical lines 119a and 119b, respectively, in turn, may be coupled to a controller 186 to measure the strain of the stretchable tail 106. The controller 186 may utilize the measurement to determine an amount of elongation or stretch of the stretchable tail 106 and, in turn, determine a position of the flexible panel area 102 from the elongation or stretch.

With additional reference to FIG. 3F, in another embodiment, the contact areas may be arranged at a common end of a section of the stretchable tail 106 formed into the helix 114. For example, the first and second electrical contact areas 117a and 117b, respectively, may be formed near the first end 116a or the second end 116b as shown. The conductive polymer 129 may be formed to provide the return path. This may enable each of the first and second electrical contact areas 117a and 117b, respectively, to be near the controller 186.

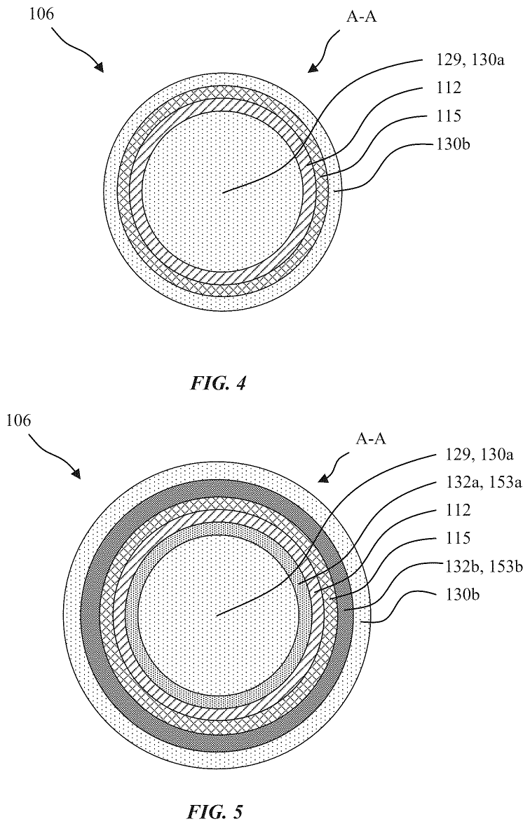

FIG. 4 is a first example (simplified) of a cross section A-A of the helix 114 of the stretchable tail 106 (in the coiled state 124 shown in FIG. 2). In this example, from inside layers to outside layers, the helix 114 may include an inner elastomer 130a, the conductive traces 112, a flexible circuit board 115 (e.g., the second flexible circuit board, forming the stretchable tail 106), and an outer elastomer 130b. The inner elastomer 130a and the outer elastomer 130b may each include a soft, high recovery elastomeric polymer or elastomer utilized to maintain a shape of the helix 114 while enabling elongation with minimal strain. The inner elastomer 130a may fill an inside of the helix 114. The outer elastomer 130b may encapsulate an outside of the helix 114, surrounding a circumference of the helix 114. In some embodiments, the outer elastomer 130b may form one or more dispensed lines of elastomer along the length of the helix 114. In various embodiments, one or more of the foregoing layers may be absent, and/or one or more additional layers may be present. In some embodiments, the inner elastomer 130a may comprise the conductive polymer 129 to configure the stretchable tail 106 to perform as a strain gauge. See, for example, FIGS. 3C, 3D, 3E, and 3F.

The layers may be coiled together to form the helix 114 in a variety of ways as described herein. In some embodiments, before coiling the stretchable tail 106 to form the helix 114, the stretchable tail 106 may be layered with the inner elastomer 130a and/or the outer elastomer 130b. After forming the helix 114, the inner elastomer 130a may fill the helix 114, and/or the outer elastomer 130b may encapsulate the helix 114, to increase recovery of the stretchable tail 106 from stretching. Alternatively, in some embodiments, the helix 114 may first be formed, then filled with the inner elastomer 130a and/or encapsulated with the outer elastomer 130b.

FIG. 5 is a second example (more complex) of a cross section A-A of the helix 114 of the stretchable tail 106 (in the coiled state 124). In this example, from inside layers to outside layers, the helix 114 may include the inner elastomer 130a, an inner shape memory layer 132a, the conductive traces 112, the flexible circuit board 115, an outer shape memory layer 132b, and the outer elastomer 130b. The inner shape memory layer 132a and the outer shape memory layer 132b may each include a shape memory material (e.g., a heat shrink polymer or alloy) utilized to coil the stretchable tail 106 into the helix 114 (e.g., without utilizing a mandrel). For example, Nitinol, a Nickel-Titanium metal alloy, may be used for the inner shape memory layer 132a and/or the outer shape memory layer 132b. Each shape memory layer may be deformed when cold (e.g., stretched out in a straight wire as shown in FIG. 1, to bond to the flexible panel area 102) and may return to a pre-deformed shape when heated (e.g., coiled in the helix 114 after bonding, as shown in FIG. 2). For example, each shape memory layer may return to the pre-deformed (programmed) shape and coil into the helix 114 when exposed to a transition temperature, e.g., the application of heat. This may provide a backbone that wraps the stretchable tail 106 into the helix shape. In various embodiments, one or more of the foregoing layers may be absent, and/or one or more additional layers may be present.

In some embodiments, one shape memory layer may be in tension and/or another shape memory layer may be in compression. For example, the inner shape memory layer 132a may be configured to be in tension, layering on the top, while the outer shape memory layer 132b may be configured to be in compression layering on the bottom. In some embodiments, only one shape memory may be present, such as either the inner shape memory layer 132a or the outer shape memory layer 132b.

FIG. 6 is an example of a plurality of modular circuits, 100a, 100b, and 100c configured in an array, each like the modular circuit 100. The plurality of modular circuits may be coupled together via stretchable tails 106a, 106b, and 106c to form an array of circuitries 120 at discrete locations. For example, modular circuit 100a may include circuitry 104a (e.g., sensors 108 and conductive traces 110) coupled to a flexible panel area 102a coupled to a stretchable tail 106a. The stretchable tail 106a may couple to the flexible panel area 102a at a first end and further couple to a flexible panel area 102b of the modular circuit 100b at a second end. The modular circuit 100b may include circuitry 104b coupled to the flexible panel area 102b coupled to a stretchable tail 106b. The circuitry 104b may include a second instance of the circuitry 104a (e.g., sensors 108 and conductive traces 110) or may include different circuitry (e.g., display pixels and conductive traces 110). The stretchable tail 106b may couple to the flexible panel area 102b at a first end and may further couple to a flexible panel area 102c of the modular circuit 100c at a second end. The modular circuit 100c may include circuitry 104c coupled to the flexible panel area 102c coupled to a stretchable tail 106c. The circuitry 104c may include a third instance of the circuitry 104a (e.g., sensors 108 and conductive traces 110) or may include different circuitry (e.g., RF circuits and conductive traces 110). The chain may continue in this way with additional circuitries to form the array of circuitries 120 until terminating by either a final, unconnected second end of a stretchable tail (e.g., the stretchable tail 106c), or a flexible panel area without a second, continuing stretchable tail (e.g., deletion of the stretchable tail 106c).

Thus, the stretchable tails may provide an interconnect between circuitries 104 of two flexible panel areas 102. The circuitries 104 of the two flexible panel areas 102 may be the same or different. For example, the stretchable tail 106a may provide an interconnect between circuitries 104a and 104b of flexible panel areas 102a and 102b, and the stretchable tail 106b may provide an interconnect between circuitries 104b and 104c of flexible panel areas 102b and 102c, respectively, each implementing sensors 108. In another example, one or more of the circuitries 104 may be different. The array of circuitries 120 may be bendable, stretchable, and deformable in 3D by stretching and bending of the various stretchable tails 106 individually. The array of circuitries 120 may be coupled or adhered to an article to form a larger modular circuit. This may include adhering to complex shapes and contours of an article, to deform with the shapes and contours of the article in 3D, while providing functionality of the individual circuitries, each in communication with a controller. For example, the array of circuitries 120 may form a sensing array coupled to a wearable article, such as a sensing glove, shoe, sock, or sleeve, or an article in the environment, such as a chair or dashboard of a vehicle. In another example, the array of circuitries 120 may form a foldable video display with pixels.

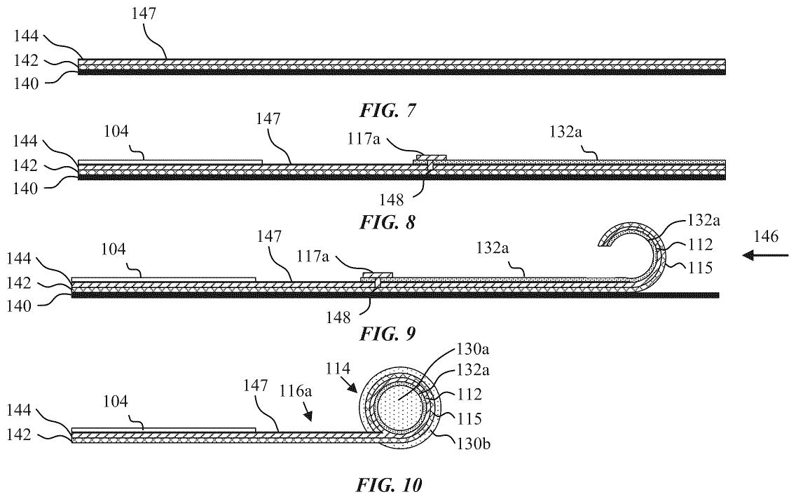

FIGS. 7-10 illustrate manufacturing the modular circuit 100 based on a process that includes layering the stretchable tail 106. In FIG. 7, a flexible circuit board 142 (e.g., polyimide) may be formed on a carrier substrate 140. The flexible circuit board 142 may be utilized to form the second flexible circuit board providing the stretchable tail 106. In some cases, the flexible circuit board 142 may also be utilized to form the first flexible circuit board providing the flexible panel area 102. A conductive layer 144 (e.g., a metal routing layer) may be formed on the flexible circuit board 142 with an insulator 147 over the conductive layer 144. The conductive layer 144 may form the conductive traces 112 extending along the length of the stretchable tail 106. In some cases, the conductive layer 144 may also form the conductive traces 110 to connect to circuitry (e.g., manufacturing the flexible panel area 102 and the stretchable tail 106 together, as opposed to manufacturing them separately and bonding them to one another). In some embodiments, the conductive layer 144 may be positioned in neutral layer (or neutral axis) of the stack up of layers, so that the conductive layer is equally between other layers when formed in the helix 114. This may enable a reduction of stress applied to the conductive traces 110 and/or the conductive traces 112 when coiled.

In FIG. 8, an inner shape memory layer (e.g., the inner shape memory layer 132a) may be formed on the flexible circuit board 142 and the conductive layer 144. The inner shape memory layer 132a may be in tension, such that an application of heat may cause the inner shape memory layer 132a to curl, pulling the flexible circuit board 142 and the conductive layer 144 away from the carrier substrate 140 into a helix (e.g., the helix 114). In some cases, an outer shape memory layer (e.g., the outer shape memory layer 132b) may also be formed between the flexible circuit board 142 and the carrier substrate 140. The outer shape memory layer 132b may be in compression such that the application of heat may cause the outer shape memory layer 132b to curl, pushing the flexible circuit board 142 and the conductive layer 144, away from the carrier substrate 140 into the helix 114. Additionally, one or more electrically conductive vias 148 may be formed through the inner shape memory layer 132a and the insulator 147 to the conductive layer 144. This may enable a conductive trace 112 of the conductive layer 144 to connect to an electrical contact area and/or a conductive polymer (e.g., the first electrical contact area 117a, and the conductive polymer 129, shown in FIG. 3E).

In some cases, circuitry (e.g., the circuitry 104) may also be coupled to the flexible circuit board 142, and electrically coupled to the conductive layer 144, at an opposite end relative to the inner shape memory layer 132a. The circuitry 104 may be applied in embodiments where the conductive layer 144 also forms the conductive traces 110. Otherwise, the circuitry 104 may be applied to another flexible circuit board using techniques described herein for bonding to exposed conductors or pads produced at the first end 116a defined in the conductive layer 144.

In FIG. 9, an application of heat 146 may cause the inner shape memory layer 132a to curl at a transition temperature, causing the inner shape memory layer 132a to return to a pre-deformed (programmed) helical shape, coiling into the helix 114. The helix 114 may include the conductive traces 112, and the flexible circuit board 115, of the of the stretchable tail 106. In some cases, the application of heat 146 may also cause the outer shape memory layer 132b to curl at the transition temperature, causing the outer shape memory layer 132b to also return to a pre-deformed (programmed) helical shape, coiling into the helix 114. Moreover, the application of heat 146 causes releasing the stretchable tail 106 from the carrier substrate 140.

The coiling may be limited to areas including the shape memory layer (e.g., the inner shape memory layer 132a and/or the outer shape memory layer 132b). For example, the shape memory layer may be applied so that the coiling only affects a portion of the flexible circuit board 142 (e.g., the mid-section of the stretchable tail 106, forming the helix 114, between the first end 116a and the second end 116b).

In FIG. 10, the helix 114 may be fully formed, with the flexible circuit board 115 and the conductive traces 112 completely separated from the carrier substrate 140, to form the modular circuit 100. In some embodiments, the helix 114 may then be filled with an inner elastomer (e.g., the inner elastomer 130a) and/or encapsulated with an outer elastomer (e.g., the outer elastomer 130b). In other embodiments, the inner elastomer 130a and/or the outer elastomer 130b may include additional layers selectively applied in FIGS. 7-8 (e.g., the inner elastomer 130a may be applied over the inner shape memory layer 132a, and the outer elastomer 130b may be applied between the flexible circuit board 142 and the carrier substrate 140, or between the outer shape memory layer 132b and the carrier substrate 140, when the outer shape memory layer 132b is present).

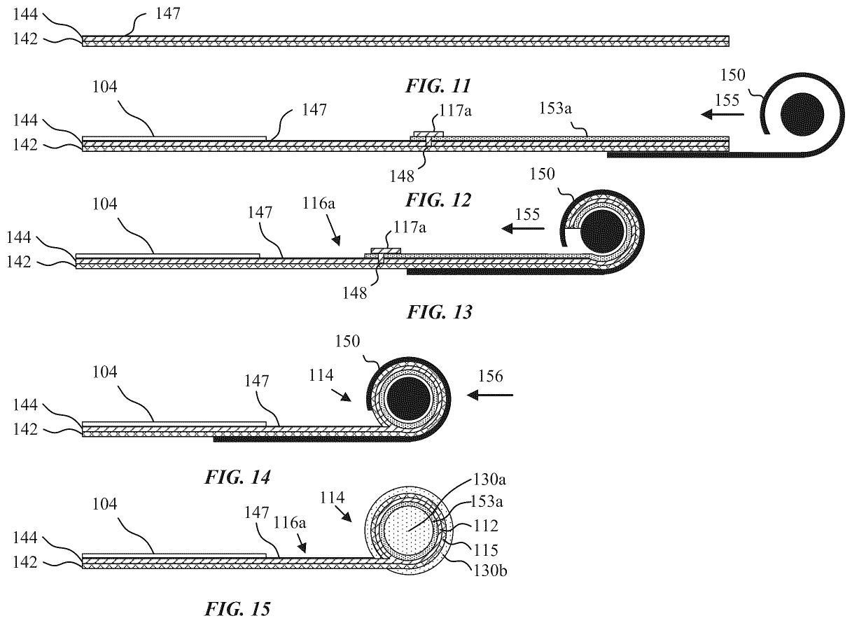

FIGS. 11-15 illustrate manufacturing the modular circuit 100 based on a process that includes winding the stretchable tail 106 with a helix forming tool 150, e.g., a cylindrical mandrel. In FIG. 11, a conductive layer 144 (e.g., a metal routing layer) may be formed on a flexible circuit board 142 with an insulator 147 over the conductive layer 144. The conductive layer 144 may form the conductive traces 112 extending along the length of the stretchable tail 106. The flexible circuit board 142 may be utilized to form the second flexible circuit board providing the stretchable tail 106. In some cases, the conductive layer 144 may also form the conductive traces 110 to connect to circuitry (e.g., manufacturing the flexible panel area 102 and the stretchable tail 106 together, as opposed to manufacturing them separately and bonding them to one another). For example, the flexible circuit board 142 may also be utilized to form the first flexible circuit board providing the flexible panel area 102. In some embodiments, the conductive layer 144 may be positioned in neutral layer (or neutral axis) of the stack up of layers, so that the conductive layer is equally between other layers when formed in the helix 114. This may enable a reduction of stress applied to the conductive traces 110 and/or the conductive traces 112 when coiled.

In FIG. 12, an inner material layer 153a may be formed on the conductive layer 144 and the flexible circuit board 142. See also FIG. 4. The inner material layer 153a may include a polymer or alloy that substitutes for the inner shape memory layer 132a of FIG. 4. In some cases, an outer material layer 153b may also be formed below the flexible circuit board 142. See, e.g., FIG. 4. The outer material layer 153b when present may include a polymer or alloy substituting for the outer shape memory layer 132b of FIG. 4. The helix forming tool 150 may begin a motion 155 toward the layers, sliding toward the inner material layer 153a, the conductive layer 144, the flexible circuit board 142, and/or the outer material layer 153b. Additionally, one or more electrically conductive vias 148 may be formed through the inner shape memory layer 132a and the insulator 147 to the conductive layer 144. This may enable a conductive trace 112 of the conductive layer 144 to connect to an electrical contact area and/or a conductive polymer (e.g., the first electrical contact area 117a, and the conductive polymer 129, shown in FIG. 3E).

In some cases, circuitry (e.g., the circuitry 104) may also be coupled to the flexible circuit board 142, and electrically coupled to the conductive layer 144, at an opposite end relative to the inner material layer 153a. The circuitry 104 may be applied in embodiments where the conductive layer 144 also forms the conductive traces 110. Otherwise, the circuitry 104 may be applied to another flexible circuit board using techniques described herein for bonding to exposed conductors or pads produced at the first end 116a defined in the conductive layer 144.

In FIG. 13, the helix forming tool 150 may begin to wind the layers, including the inner material layer 153a, the conductive layer 144, the flexible circuit board 142, and/or the outer material layer 153b when present. The helix forming tool 150 may continue the motion 155 toward the layers to wind at least a portion of the stretchable tail 106 into a helix (e.g., the mid-section of the stretchable tail 106, forming the helix 114, between the first end 116a and the second end 116b).

In FIG. 14, a long flex of the stretchable tail 106 may be wrapped around a small diameter (e.g., less than 1 mm, such as 800 μm) of the helix forming tool 150, in the shape of the helix 114, defining the helical shape of the portion of the stretchable tail 106. The helix forming tool 150 may complete winding of the layers, including the inner material layer 153a, the conductive layer 144, the flexible circuit board 142, and/or the outer material layer 153b when present, into the helix 114. The helix forming tool 150 may stop the motion 155 when winding of the portion of the stretchable tail 106 into the helix 114 is complete.

In FIG. 15, the helix forming tool 150 may hold the layers in a coiled position, coiling in the helix 114, while an application of heat 156 causes the helix 114 to maintain the helical shape. The application of heat 156 may perform a curing, annealing, or setting of the helix 114 to normalize stresses of the inner material layer 153a (and/or the outer material layer 153b when present) to maintain the shape.

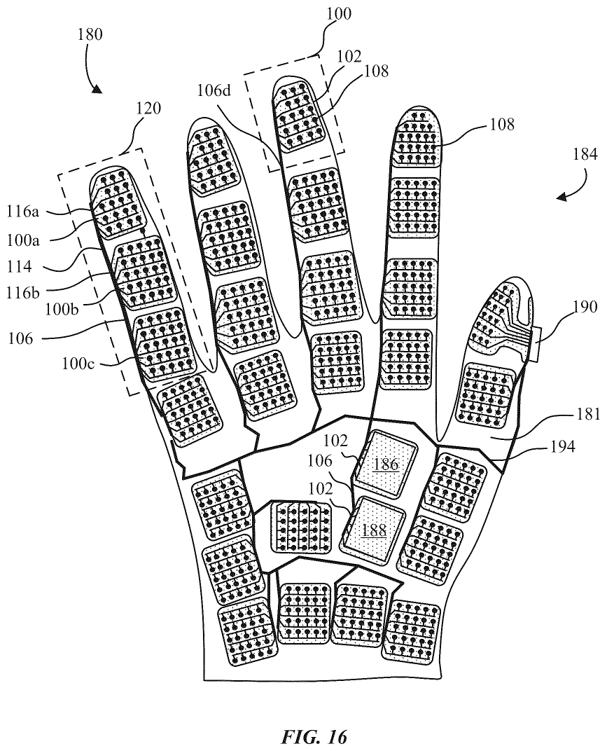

In FIG. 16, the stretchable tail 106 may be removed from the helix forming tool 150, with the helix 114 fully formed and cured. In some embodiments, the helix 114 may then be filled with an inner elastomer (e.g., the inner elastomer 130a) and/or encapsulated with an outer elastomer (e.g., the outer elastomer 130b). In other embodiments, the inner elastomer 130a and/or the outer elastomer 130b may include additional layers selectively applied in FIGS. 11-12 (e.g., the inner elastomer 130a may be applied over the inner material layer 153a, and the outer elastomer 130b may be applied below the outer material layer 153b when present.

Thus, the modular circuit 100 may be manufactured with an extra-long stretchable tail 106 that may be post processed to coil up a digital bus into a helix 114. The stretchable tail 106 may include exposed conductors or pads at opposing ends for bonding to other flexible panel areas at the opposing ends. In some embodiments, the stretchable tail 106 may utilize one or more shape memory layers. In some embodiments, the stretchable tail 106 may be wound around a small diameter (e.g., less than 1 mm) cylindrical mandrel. Either process may result in a small diameter flexible circuit board in a helical shape. This helical shape may make the flexible circuit board of the modular circuit 100 further flexible while also enabling recoverable stretchability.

FIG. 16 is a schematic layout view illustration of a sensing system 180 including a plurality of modular circuits 100 in accordance with an embodiment. The sensing system 180 may perform an integrated readout of circuitries 104 of modular circuits 100 (e.g., sensors 108, in an array of circuitries 120) as described herein. The modular circuits 100 may be integrated with a surface 181 of an article 184 which may be deformable with the modular circuits 100 and/or have limited space. For example, the sensing system 180 may be a wearable system that is integrated with a sensing glove worn by a user. The sensing glove may have digits (four fingers and a thumb), each digit having digit sections defined by knuckles. The modular circuits 100 may have circuitries 104 that include, for example, 1,000 sensors, 10,000 sensors, or more, integrated with the article 184. Each circuitry 104 may include a plurality of sensors 108 arranged in a location of the article 184. For example, a first modular circuit 100a may correspond to a first group of 10 sensors, 100 sensors, or more, with a first flexible panel area arranged to cover a first finger (first digit) or fingertip (digit section) of the sensing glove, a second modular circuit 100b may correspond to a second group of 10 sensors, 100 sensors, or more, with a second flexible panel area arranged to cover a second finger (second digit) or fingertip (digit section) of the sensing glove, and so forth. The stretchable tails may be coupled between the flexible panel areas, including alongside a knuckle such as stretchable tail 106d. This may enable electrical connectivity between circuitries 104 coupled to areas that move with respect to one another, such as circuitries 104 on opposite sides of the knuckle. Some circuitries 104 of the modular circuits 100 in the sensing system 180 may implement other functions, such as display pixels for display areas, controllers, RF circuits for communications, etc.

The sensing system 180 may include a controller 186 (e.g., another circuitry 104, which may be implemented by an application-specific integrated circuit (ASIC) or field-programmable gate array (FPGA) coupled to a flexible panel area 102) connected to the plurality of modular circuits 100 and to a communication device 188 (another circuitry 104, which may include an integrated circuit (IC) and an antenna) coupled to a flexible panel area 102 with wiring 194, e.g., implemented by a stretchable tail 106. For example, the modular circuits 100 and sensors 108 could be on a palmar side of a sensing glove, and the controller 186 and the communication device 188 could be on the palmar side or a dorsal side of the sensing glove. The modular circuits 100 can be exterior facing to an environment or internally facing to a user, or both. The controller 186 and communication device 188 are illustrated as being on the palmar side in FIG. 7 for illustrative purposes, though may also or alternatively be located on the dorsal side of the sensing glove, on a thumb, etc. The controller 186 may connect directly and/or indirectly to other modular circuits 100 and the sensors 108 thereof. For example, in some cases, the controller 186 may connect directly to the sensors 108, and in other cases, the controller 186 may be a global controller connected to one or more local controllers (implemented by other circuitries 104) that are connected to the sensors 108. For example, the controller 186 could connect to a local controller 190 (e.g., another IC, such as an ASIC or FPGA) arranged on a section of the article 184 (e.g., a dorsal side of a thumb of the sensing glove). The local controller 190, in turn, may connect to sensors 108, of one or more modular circuits 100, in the section (e.g., the thumb). The local controller 190 can process outputs (e.g., digital outputs) from sensors 108 in the section to generate a compressed bitstream for the controller 186. In some embodiments, the controller 186 may be a hybrid controller operating as both a global controller (e.g., connected to local controllers arranged in some sections of the article 184) and a local controller (e.g., connected directly to sensors 108 in other sections of the article 184).

In operation the controller 186 can cause one or more sensors 108 of one or more modular circuits 100 to each transmit an output. In some cases, the controller 186 can directly cause transmission of an output from a sensor 108, such as by sending an input to trigger a sensor 108. In other cases, the controller 186 can indirectly cause transmission of an output from a sensor 108, such as by causing a local controller to send an input to trigger a sensor 108, and/or by causing one sensor 108 to send an output to trigger another sensor 108.

The communication device 188 may enable the transmission of a collection of data from sensors 108 to another system. The communication device 188 may utilize wired or wireless connections, such as universal serial bus (USB), low-voltage differential signaling (LVDS), serial peripheral interface (SPI), Bluetooth, or Ethernet, to transmit the digital data. For example, the controller 186 can receive outputs from the sensors 108 based on triggering those sensors, then utilize the communication device 188 to transmit a compressed bitstream encoding the outputs to another system, such as a host computer or server. As a result, the controller 186 can selectively perform readout of sensors 108, of modular circuits 100, in the sensing system 180 to obtain sensing information fast and with high resolution.

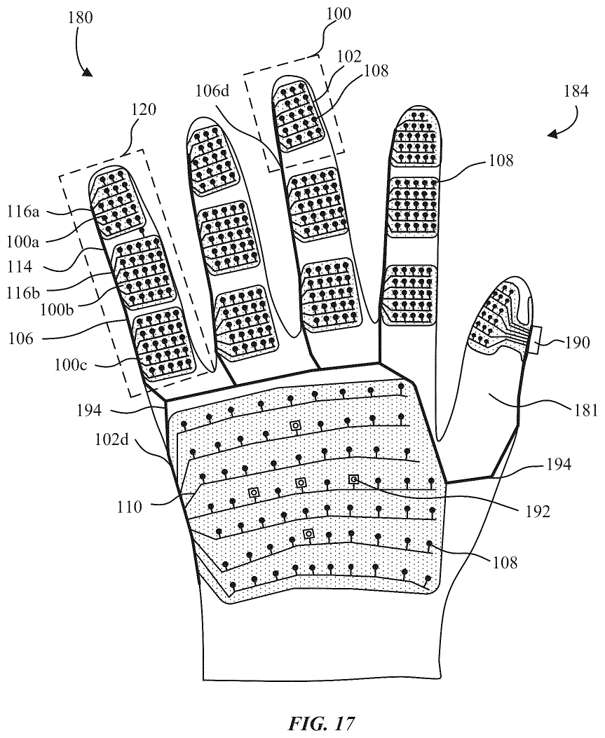

FIG. 17 is a schematic layout view illustration of a sensing system 180 including a plurality of modular circuits 100 in accordance with an embodiment. The sensing system 180 of FIG. 16 is substantially similar to that illustrated in FIG. 17, though illustrates that modular circuits 100 of different size, including sensors 108 with different pitch, can be integrated. In some embodiments, sensors 108 within modular circuits 100 coupled with some regions of the article (see the flexible panel area 102d located on the palmar area) may have an increased size, and decreased pitch of sensors 108, compared to sensors 108 in modular circuits 100 coupled with other regions of the article. For example, sensors 108 in the modular circuits 100 coupled with fingertip regions or other finger regions may have a smaller pitch (e.g., a closer spacing between sensors), such as 2 mm or less or 1 mm or less, while sensors 108 coupled with the palm may have a greater pitch (e.g., a further spacing between sensors), such as greater than 1 mm, 2 mm, 3 mm, or 5 mm or more. Sensor 108 pitch across circuitries 104 can be constant, or may be graded for example, from a tighter to coarser pitch for example, and vice versa. Sensor 108 pitch can also be varied at specific locations to facilitate the inclusion of additional devices or alternative sensors. For example, one or more cameras 192 may be dispersed within the circuitry 104 of a modular circuit 100. The one or more cameras 192 may be utilized to detect color data (e.g., RGB) and/or depth data (e.g., spatial orientation) of objects while performing a task. The controller 186 and/or the communication device 188 may be on the dorsal side of the sensing glove.

In other applications, the sensing system 180 including the plurality of modular circuits 100 may be coupled to upholstery, sleeves, shoes, chairs, etc., and/or may be integrated with large area tactile input surfaces, such as a curved vehicle dashboard, having software-reconfigurable buttons, switches, and/or dials.

Reference is now made to flowcharts of examples of processes for manufacturing modular circuits with flexible panel areas and stretchable tails. The processes can be executed using systems, hardware, and software described with respect to FIGS. 1-16. For simplicity of explanation, the processes are depicted and described herein as a series of operations. However, the operations in accordance with this disclosure can occur in various orders and/or concurrently. Additionally, other operations not presented and described herein may be used. Furthermore, not all illustrated operations may be required to implement a process in accordance with the disclosed subject matter.

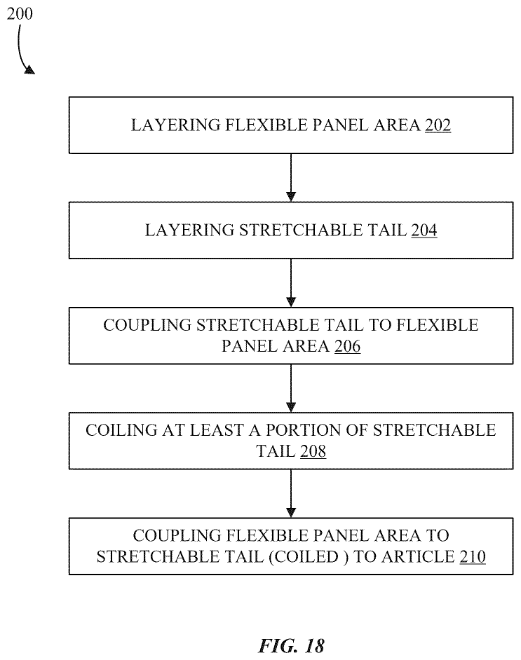

FIG. 18 is an example of a process 200 for manufacturing modular circuits 100. At operation 202, the manufacturing may include layering a flexible panel area 102. This may include coupling circuitry 104 to the flexible panel area 102. The flexible panel area 102 may include a plurality of conductive traces 110 extending from an interior to a side of the flexible panel area 102 for bonding to, and electrically connecting with, one or more stretchable tails 106. For example, FIGS. 7-8 illustrate layering circuitry 104 on a flexible circuit board 142 and a conductive layer 144 to form a flexible panel area 102 conductive traces 110 according to one process. FIG. 11-12 illustrates layering circuitry 104 on a flexible circuit board 142 and a conductive layer 144 to form a flexible panel area 102 according to another process.

At operation 204, the manufacturing may include layering a stretchable tail 106 106. The stretchable tail 106 may include a plurality of conductive traces 112 extending along a length of the stretchable tail 106. The conductive traces 112 may include exposed conductors 113a or pads (first exposed conductors) at a first end 116a and exposed conductors 113b or pads at a second end 116b (second exposed conductors) to enable bonding at either end to a flexible panel area with electrical connectivity. For example, FIG. 8 illustrates layering a shape memory layer (e.g., the inner shape memory layer 132a) relative to the flexible circuit board 142 and the conductive layer 144 to form a stretchable tail 106 according to one process. FIG. 12 illustrates layering a material layer (e.g., the inner material layer 153a) relative to the flexible circuit board 142 and the conductive layer 144 to form a stretchable tail 106 according to another process.

At operation 206, the manufacturing may include coupling the stretchable tail 106 to the flexible panel area 102. The plurality of conductive traces 112 of the stretchable tail 106 may be coupled to the conductive traces 110 of the circuitry 104 of the flexible panel area 102, Specifically, the exposed conductors 113a may be bonded to the exposed conductors 111, such as via ACF bonding. In some embodiments, the stretchable tail 106 may be uncoiled as shown in FIG. 1 when bonding to the flexible panel area 102. In some embodiments, the stretchable tail 106 may be coiled as shown in FIG. 2 when bonding to the flexible panel area 102.

At operation 208, the manufacturing may include coiling at least a portion of the stretchable tail 106 into the helix 114. The coiling may be performed either before or after coupling the stretchable tail 106 to the flexible panel area 102. In some cases, the helix forming tool 150 may be used to coil the stretchable tail 106. In some cases, a shape memory material, e.g., a polymer or alloy, such as the inner shape memory layer 132a and/or the outer shape memory layer 132b, may be used to coil the stretchable tail. In some cases, a material layer, e.g., a polymer or alloy, such as the inner material layer 153a, may be used to coil the stretchable tail 106. In some cases, an elastomer, such as the inner elastomer 130a filling the helix 114, or the outer elastomer 130b encapsulating an outside of the helix 114, may be applied to the stretchable tail 106 to increase recovery from stretching of the stretchable tail 106.

At operation 210, the manufacturing may include coupling or adhering the flexible panel area 102 to the stretchable tail 106 coiled in the helix 114 (forming the modular circuit 100) to an article. For example, the modular circuit 100 may be coupled or adhered to a sensing glove, such as to form the sensing system 180. In other applications, the modular circuit 100 may be coupled or adhered to upholstery, sleeves, shoes, chairs, etc., and/or may be integrated with large area tactile input surfaces, such as a curved vehicle dashboard, having software-reconfigurable buttons, switches, and/or dials.

As used herein, the term “circuitry” refers to an arrangement of electronic components (e.g., transistors, resistors, capacitors, and/or inductors) that is structured to implement one or more functions. For example, a circuit may include one or more transistors interconnected to form logic gates that collectively implement a logical function, including sensors of a sensor array, display pixels, radio frequency (RF) circuits, conductive traces, etc.

In utilizing the various aspects of the embodiments, it would become apparent to one skilled in the art that combinations or variations of the above embodiments are possible for modular circuits with flexible panel areas and stretchable tails, including manufacture of same. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A modular circuit, comprising:
a flexible panel area;
circuitry coupled to the flexible panel area; and
a stretchable tail coupled to the flexible panel area, wherein the stretchable tail includes a plurality of conductive traces extending along a length of the stretchable tail, the plurality of conductive traces coupled to the circuitry.

2. The modular circuit of claim 1, wherein the stretchable tail is coiled in a helix.

3. The modular circuit of claim 1, wherein the stretchable tail is encapsulated in an elastomer that increases recovery from stretching.

4. The modular circuit of claim 1, wherein the stretchable tail is filled with an elastomer that increases recovery from stretching.

5. The modular circuit of claim 1, wherein the stretchable tail is filled with a conductive polymer for measuring strain.

6. The modular circuit of claim 1, wherein the stretchable tail includes a shape memory material that coils the stretchable tail.

7. The modular circuit of claim 1, wherein the plurality of conductive traces includes first exposed conductors at a first end of the stretchable tail bonded to the circuitry.

8. The modular circuit of claim 1, wherein the plurality of conductive traces includes second exposed conductors at a second end of the stretchable tail.

9. The modular circuit of claim 1, wherein the plurality of conductive traces implement a digital bus for communicating with the circuitry.

10. The modular circuit of claim 1, wherein the circuitry includes a plurality of sensors for sensing an environment.

11. A method for manufacturing a modular circuit, comprising:
coupling circuitry to a flexible panel area;
coupling a stretchable tail to the flexible panel area, wherein the stretchable tail includes a plurality of conductive traces extending along a length of the stretchable tail, the plurality of conductive traces coupled to the circuitry; and
coiling at least a portion of the stretchable tail.

12. The method of claim 11, wherein coupling the stretchable tail includes bonding exposed conductors of the plurality of conductive traces to exposed conductors of the circuitry.

13. The method of claim 11, wherein coiling includes wrapping the stretchable tail around a mandrel.

14. The method of claim 11, further comprising:
annealing the stretchable tail to normalize stresses of the stretchable tail after coiling.

15. The method of claim 11, wherein coiling includes exposing a shape memory material of the stretchable tail to a transition temperature.

16. The method of claim 11, wherein coiling includes releasing the stretchable tail from a carrier substrate to enable a shape memory material to coil the stretchable tail.

17. The method of claim 11, further comprising:
encapsulating the stretchable tail in an elastomer after coiling to increase recovery from stretching of the stretchable tail.

18. A modular system, comprising:
a plurality of flexible panel areas coupled to an article, each flexible panel area having circuitry coupled thereto; and
a stretchable tail coupled between flexible panel areas of the plurality of flexible panel areas, wherein the stretchable tail includes a plurality of conductive traces extending along a length of the stretchable tail, the plurality of conductive traces coupled to the circuitry of the flexible panel areas.

19. The modular system of claim 18, wherein the article is a sensing glove with digits having digit sections defined by knuckles, and wherein the plurality of flexible panel areas is arranged to cover the digit sections.

20. The modular system of claim 18, wherein the stretchable tail is configured as a strain sensor.
